(19) United States
(12) Patent Application Publication
(10) Pub. No.: US 2015/0198681 A1
(43) Pub. Date: Jul. 16, 2015

(54) Method for transporting an NMR sample spaced horizontally and vertically from a cryo-magnetic system using a vibration isolated motorized curvilinear Transport Carrier with dual end-effector and method for telescoping the Carrier to different cryo-magnetic systems at different heights

(71) Applicant: PRUDHVI RAJU CHINTALAPATI, IRVING, TX (US)

(72) Inventor: PRUDHVI RAJU CHINTALAPATI, IRVING, TX (US)

(21) Appl. No.: 14/155,797

(22) Filed: Jan. 15, 2014

(51) Int. Cl. G01R 33/30; G01R 33/46

(52) U.S. Cl. CPC G01R 33/307; G01R 33/46

(57) ABSTRACT

An electro-mechanical curvilinear transport Carrier is used for transporting an NMR sample (3) spaced horizontally and vertically from the input point (A) to the supply point (B). The sample (3) contains an NMR sample test tube (1) inserted into a container (2). This sample (3) is loaded into a transport Carrier (4) either manually or automatically with a robot (5). The transport Carrier (4) loading position (A) is at an ergonomic sitting eye height between 31-38 inches. The transport Carrier (4) moves along a curvi-linear rail (6). The transport Carrier (4) has two slides (4a) capable of holding one sample (3) each. The slides (4a) can go up or down to either load or unload the sample at the supply point (B). The slides (4a) are operated either pneumatically or electro-mechanically with a piezo motor (not shown). The transport carrier (4) includes a piezo motor (not shown) to ensure that the samples (3) are always held vertical irrespective of the transport carrier (4) position along the curvi-linear rail. This is accomplished by input from a gyro sensor (not shown) on the transport carrier (4). At the supply point (B), the slides can load or unload the sample into the Room Temperature (RT) tube of the Cryostat (7). Once inside the RT Tube, the sample is carried into the final position (D) of the NMR test using a pneumatic actuator (not part of this patent). There are several variants of the NMR magnets (8) based on different magnetic strengths and heights. To accomplish different heights for magnets of varying strengths, the curvi-linear rail (6) can be telescoped to different heights on another floor attachment (9) with plurality of holes for attaching the curvi-linear rail (6) for each magnet height.

### CROSS-REFERENCE TO′RELATED APPLICATIONS

The present application claims the benefit of U.S. Provisional Application No. 61/752,723 filed on 15^{th} of January 2013.

### UTILITY PATENT APPLICATION

Method for transporting an NMR sample spaced horizontally and vertically from a cryo-magnetic system using a vibration isolated motorized curvilinear Transport Carrier with dual end-effector and method for telescoping the Carrier to different cryo-magnetic systems at different heights.

### STATEMENT REGARDING FEDERALLY SPONSORED RESEARCH OR DEVELOPMENT

Not Applicable

### REFERENCES CITED

U.S. PAT. DOCUMENTS

| | | |
|---|---|---|
| 7,764,064 B2 | August 2010 | Reiss et all |
| 8,217,655 B2 | August 2012 | De Vries et all |

### BACKGROUND OF THE INVENTION

The invention concerns a transport device for conveying an NMR (Nuclear Magnetic Resonance) measuring sample (3) between an input point (A) and a supply point (B). The input point (A) is spaced horizontally and vertically from the supply point (B). The input point (A) is at an ergonomic sitting eye height between 31-38 inches from the floor, where the sample (3) is submitted either manually or automatically with a robot or similar automation accessory (5). A Transport Carrier (4) is used to transport the sample from the input point (A) either electro-mechanically or pneumatically around a curvilinear rail (6) to the supply point (B) where the sample (3) is inserted into the Room Temperature Tube (RT Tube) (7) of the Cryostat.

NMR Spectrometers operated along with a fast computer are used to enable the application of the Fast Fourier Transformed spectrometry (FFT-NMR) to reveal specific physical and/or chemical properties of liquid or solid samples. They are used in academia, pharmaceutical, petro-chemical or other similar applications where it is vital to know the properties of a sample. NMR Spectrometers are almost exclusively operated with superconducting cryo-magnet systems (called as “Magnet” henceforth) with fields of up to 20 Tesla. An NMR experiment is extremely sensitive to external vibrations. A vibration as simple as a truck driving past an NMR laboratory housing a magnet can impact the NMR experiment. To minimize the impact of vibrations, the magnet is mounted on three vibration-isolated legs (10).

The installed computer not only enables performance of fast FFT but can also be used for automation tasks such as e.g. automated transport of the NMR measuring sample (3) from an easily accessible user location (input point A) to the magnetic center (D) of the magnet and back. This automated transport is very advantageous in particular for high field magnets with fields ranging from 16 Tesla and above since these magnet systems may have a height of 2.5 meters or above and the NMR measuring sample is introduced at the upper area of the magnet system at the supply point (B).

The process of preparing a sample involves filling a sample tube (1) with the desired liquid or solid to a certain level and then inserting the sample tube (1) into a container (2) {also called a turbine} to a certain depth so that the liquid or solid is exposed and is at a certain level for an optimized NMR spectroscopy experiment.

Several variants of automated transport devices are available depending on the required throughput (i.e. number of samples to be processed continuously). An NMR experiment for a single sample can take anywhere from a few seconds to several hours. Sometimes it may be necessary to test a single sample where the user walks up to the magnet and submits the sample to the automated transport device manually at the input point (A). Sometimes it is necessary to perform an NMR experiment on several hundreds of samples where the automated transport device picks up the samples sequentially or in a particular order and submits them to the magnet for NMR testing. In this case the user submits a magazine containing several samples at the input point (A). The user selects the samples that need to be processed for the NMR experiment on the computer.

The “Sample Mail” [1] of the company Bruker is a conventional transport device that is capable of handling a single sample. The device is attached to the Magnet as shown in FIG. 1. The “Sample Mail” [1] uses two mechanisms; one to pneumatically push the sample vertically up through a transport tube (11) from a user accessible input point (A) to the intermediary location (C) between the mechanisms. When the sample is pneumatically pushed up to the intermediary location (C) a gripper at location (C) “catches” the sample and holds it in place to allow the sample to move along the second mechanism. The second mechanism uses a linear actuator (LTM) to push the sample held by the gripper, from the intermediary location (C) to the supply point (B) for insertion into the Room Temperature tube of the cryostat. The pneumatic supply for the mechanisms is provided either from a lab outlet for Clean Dry Air at pressures up to 100-120 psi or from a cylinder containing the pressurized Clean Dry Air.

One further conventional transport device is the “Sample Case” [2] of the company Bruker. It is similar to “Sample mail” [1] except that now we can submit up to 24 samples in a sequential or a user selected order, one sample at a time, at the input point (A). The user selects the samples that need to be processed on a computer. Based on the sequence, the “Sample case” [2] will transport the sample via the transport tube (11) and the linear actuator (LTM) to the supply point in the same way as the “Sample Mail” [1]. This device is also attached to the Magnet as shown in FIG. 2.

The advantage of using this approach is that the samples can be submitted at a user accessible height at the input point (A). However this simple design also comes with several disadvantages.

One disadvantage is the requirement that the inner diameter of the transport tube (11) be tightly controlled for diametric tolerance with respect to the outer diameter of the turbine (2). The turbine (2) can get “caught” inside the transport tube (11) if the inner diameter of the tube is less than the outer diameter of the turbine (2). If the inner diameter of the transport tube (11) is much larger than the Outer diameter of the turbine (2), then due to air leak, the turbine may not have enough pressure to be pneumatically pushed up the tube. Since the transport tube material is plastic it is difficult to accurately control the inside diameter of the tube through existing manufacturing processes and the above defined issues may arise.

Also in certain cases it may be necessary to cool or preheat the sample before inserting into the magnet. The thermal expansion of the turbine (2) can cause the turbine (2) to be caught up along the transport tube (11). It is also possible that the transport tube (11) be cinched by accident or damaged due to wear and tear that may prevent the sample from moving up and down smoothly as required.

Another disadvantage is due to the varying heights of the Magnet. As the Magnetic field strength (measured in Tesla) increases, their height also proportionally increases. The heights can vary from lows of 1.6 meters to as high as 3 meters or above from floor of the lab. This limits the usage of the Sample mail [1] and Sample Case's [2] transport tubes, which need to be cut to length for each unique height of the magnet. The transport tubes cannot be cut at the customer site due to the complexity of the location of the vacuum seals and the tools required to accomplish this task. Thus the transport tubes cannot be telescoped as such that a single transport tube be capable of being used on all variants of magnet heights. This creates a high cost of managing inventory for transport tubes of each unique size. FIG. 3 shows 2 unique transport tubes for each unique height of the magnet.

A further conventional transport device is the “Sample Changer” ASC [4] of the company JEOL. It is a sample carousel automated device that is available with magazine capacities of 8, 16, 24 or 64 samples to be transported. The samples can be supplied to the NMR measurement individually, in selected or sequential order.

A further conventional transport device is the “7510 Auto sampler” [3] of the company Varian (acquired by Agilent Technologies). It is a sample carousel automated device that is available with magazine capacities of 12 samples to be transported. The samples can be supplied to the NMR measurement individually, in selected or sequential order.

A further conventional transport device is the “Sample Express” [5] of the company Bruker. It is a sample carousel automated device that is available with magazine capacities of 60 samples to be transported. The samples can be supplied to the NMR measurement individually, in selected or sequential order.

Another conventional device is the “Sample Jet” [7] of the company Bruker. The Sample Jet [7] has a magazine capacity of 480 NMR samples tubes that can be supplied in the form of 5 cassettes of 96 pieces of the sample tube. The Sample Jet [7] is capable of inserting the sample tube in the turbine (2) to submit to the supply point (B) of the Room Temperature tube of the Cryostat.

The above 4 devices (Sample Changer ASC [4], 7510 Auto Sampler [3], Sample Express [5] and Sample Jet [7]) are all attached to the top of the magnet mounted to a fixture on top of the supply point (B). The major disadvantage of this approach is that in order to submit the samples for the experiment, the user needs to climb a ladder or a scaffolding device to reach the top of the magnet and mount the Automation device. This approach is inconvenient and risky, as it requires that the user climb a ladder and then reaches out to the center of magnet for submitting the automation device. Also it is almost impossible for people with disabilities to be able to perform any kind of experiment where it is extremely difficult to reach the top of the magnet.

A major disadvantage of all the above-described devices is that they are all mounted to the magnet. NMR experiments are extremely sensitive and as such the magnets are mounted on vibration-isolated legs to prevent any external vibrations from affecting the NMR experiment. By mounting the above devices to the magnet, any inherent vibrations in the mechanisms are transmitted directly to the magnet and can negatively impact the experiment. Devices such as the “Sample Express”[5] and “Sample Jet [7]” are heavy, weighing up to 50 lbs. or more and as such cause the magnet to tilt and rely on the vibration-isolated legs to compensate for the tilt.

Another conventional device is the “7620 Auto Sampler” [6] of the Company Agilent Technologies. To prevent causing any vibrations to the magnet, the “7620 Auto Sampler” is mounted standalone adjacent to the magnet. The device consists of a large metal structure next to the magnet and on top of the structure a SCARA Robot is attached. Two magazines with 48 samples each are located at the top of the tower adjacent to the robot. This robot picks and places these samples in and out of the RT tube at the supply point B.

By mounting standalone next to the Magnet, the “7620 Auto Sampler” doesn't cause any vibrations to the magnet. However it still lacks user accessibility in that the user has to reach up above at least 1.6 meters height to place the magazine with the NMR samples for the robot to manipulate back and forth between the magazine and the supply point B.

Also the structure utilized to mount the SCARA robot needs to be extremely rigid and strong which raises the cost excessively.

The proposed invention discloses an inexpensive, high throughput, user accessible, telescoping, transport device capable of reliably transporting the sample from an input point A to the supply point B.

### SUMMARY OF THE INVENTION

This object is achieved in accordance with the invention in that a single curvilinear rail (6) is provided to transport the sample from the input point to the supply point. The curvilinear rail (6) is vertically arranged and the length and width of the rail (6) and the curvilinear radius be adjusted to cover all magnets with a single curvilinear rail (6) dimension. The use of a curvilinear rail (6) replaces the need for two separate mechanisms to move the sample spaced horizontally and vertically from the input point to the supply point.

The curvilinear rail (6) is mounted to two legs that are attached permanently to the floor at a radial offset distance from the center of the magnet. Alternately, the legs can also be attached to the magnets vibration-isolated legs. The curvilinear rail (6) and the legs it mounts to, have several sets of equally spaced holes placed two inches apart, so that the rail (6) can be mounted to the legs and adjusted to accommodate for all heights of the magnets. This enables the use of a single curvilinear rail (6) and legs for all magnet heights and has a one-size-fits-all option. The profile of the curvilinear rail (6) enables guiding a wheeled Carrier.

A Transport Carrier (4) is guided along the curvilinear rail (6), mounting on a track outside the rail (6). The Transport Carrier (4) has 4 wheels to steer around the track and it moves forward/backward along the length of the rail (6) using an electric motor with a belt. Alternately the Carrier can also be guided using a pneumatic actuator with a belt. The motor or the pneumatic actuator used to drive the Carrier is placed away outside the strong magnetic field of the magnet. The belt used to drive the actuator uses an electric or pneumatic brake to hold the belt in position in case there is a power loss for the electric motor or if there is pressure loss for the pneumatic motor. A rotary link is attached to the Carrier, which is always held in a horizontal position either with a mechanical linkage or with a pneumatic or a piezo-electric motor no matter where the Carrier position is on the rail (6). This is accomplished with use of a gyro sensor. The rotary link has 2 or more slides to receive samples. A gripper is provided for each slide that grabs the outer diameter of the sample holder (turbine). The slides can be moved vertically up and down and with the gripper is able to pick up or release the sample at the supply point. The slider and the gripper can be actuated pneumatically or electrically using a piezo-electric motor. At the input point, the sample can be submitted into the slide manually or automatically with a robot.

The input point is arranged at an ergonomically sitting eye height at 31-38 inches from the floor, where the user can insert the sample easily. The ergonomic sitting eye height of 31-38 inches from the floor enables access to the input point even if the user is sitting on a chair and also enables any user with disabilities to even access the input point. When the transport device is assembled on site, the curvilinear rail (6) and the legs it mounts to can be so arranged that the input point is at this ergonomic sitting eye level (31-38 inches) and the supply point is at an access location above the Room Temperature tube. In addition the Transport Carrier (4) has slides that provide additional height to cover for any offsets in height between the magnet supply point and the end point of the Carrier.

At the input point, the rotary link on the Transport Carrier (4) is always held parallel to the floor such that the sample is held vertical (in line with Earths gravitational pull). As the Transport Carrier (4) begins to traverse along the rail (6), the rotary link is actuated by a linkage mechanism or with a motor to keep the link always parallel to the floor. For increased throughput two slides are provided on the rotary link. Each of the slides can receive the sample and can both insert or retrieve the sample from the supply point. At the input point a robot can be used for inserting samples into the slide. Alternately the robot can also be used to plainly insert the test tube into a turbine attached to the slider. In cases where high throughput is required a robot capable of handling test tubes from a Well plate may be a perfect fit. A well plate is a 96 sample test tubes held in an array of 12 rows and 8 columns. The well plate is a commonly used sample magazine used in other lab automation devices.

Further advantages of the invention can be extracted from the description and the drawing. The features mentioned above and below may be used individually or, collectively in arbitrary combination. The embodiments shown and described are not to be understood as exhaustive enumeration but have exemplary character for describing the invention.

### BRIEF DESCRIPTION OF THE DRAWINGS

FIG. 1 schematically shows a functional principle of a conventional first transport device according to [1]

FIG. 2 schematically shows a functional principle of a conventional second transport device according to [2]

FIG. 3 schematically shows the need of different transport tubes (11) for different magnet heights for transport devices [1] and [2] respectively.

FIG. 4 schematically shows a functional principle of conventional transport devices according to [3,4]

FIG. 5 schematically shows a functional principle of a conventional transport device according to [5]

FIG. 6 is a schematic side view of a first embodiment, wherein the object to be transported is moved back and forth in an automated fashion via curvilinear motion between a location that is easily accessible to the operating staff and the upper end of the RT tube of an NMR cryostat;

FIG. 7a is a schematic top view of a second embodiment of the inventive transport device, the transport Carrier (4) in which the sample to be transported is supplied at the input point (A). The illustration shows two samples (3) held by grippers (4a) on each slide (14) which are attached to the rotary link (16)

FIG. 7b. is a schematic side view of the second embodiment of the inventive transport device, the transport Carrier (4). Shown are the 4 wheels (17) that ride along the curvilinear track.

FIG. 7c. is a schematic front view of the second embodiment of the inventive transport device, the transport Carrier (4).

FIG. 7d. is a schematic front view of the second embodiment of the inventive transport device, the transport Carrier (4) when it is at the supply position (B). Note the location of the slides (4a) which move up/down to pick up or drop the samples (3).

FIG. 8 shows different snapshots of the transport Carrier (4) along the curvilinear rail (6). Note the orientation of the rotary link (16) as it traverses along the track. It also shows that the input point is 31-38 inches from the floor to enable ease of access to all including people confined to a chair due to any disability.

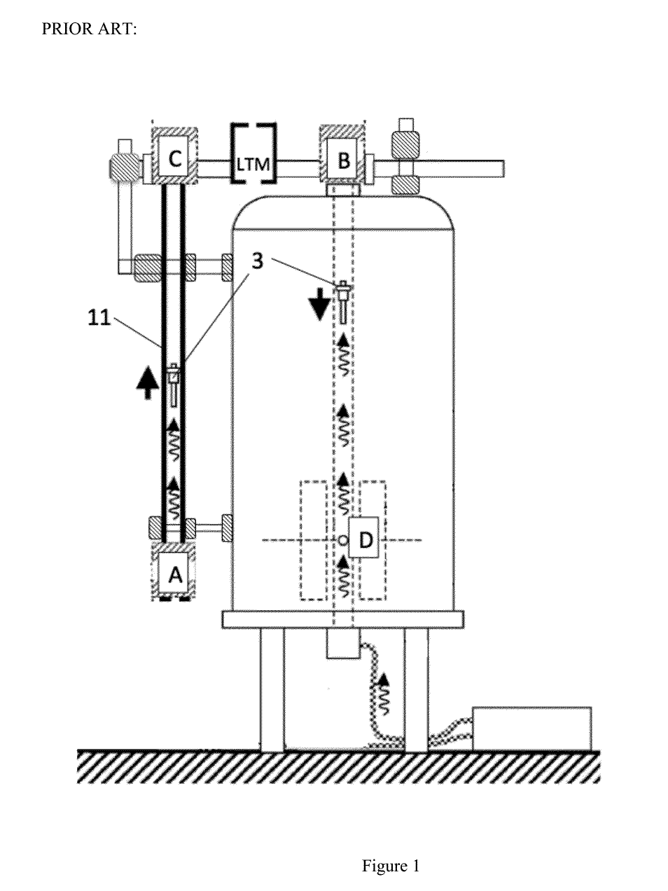

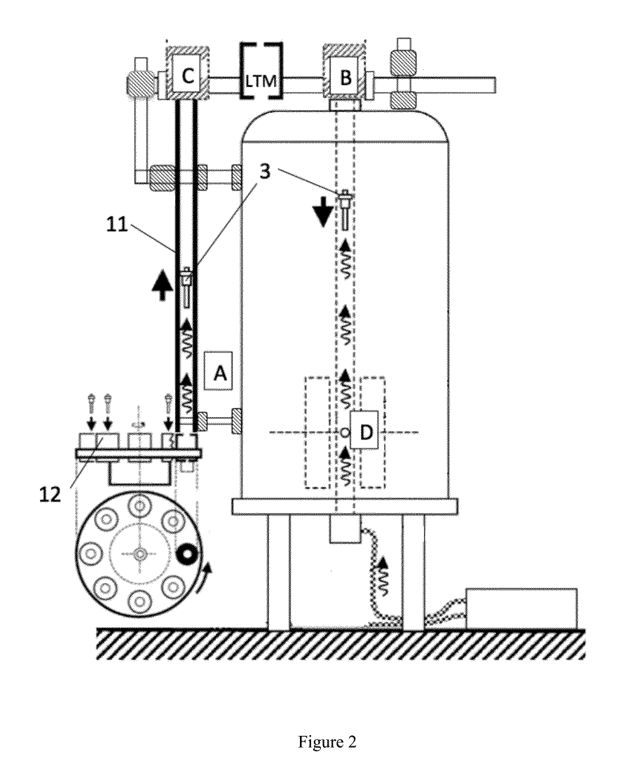

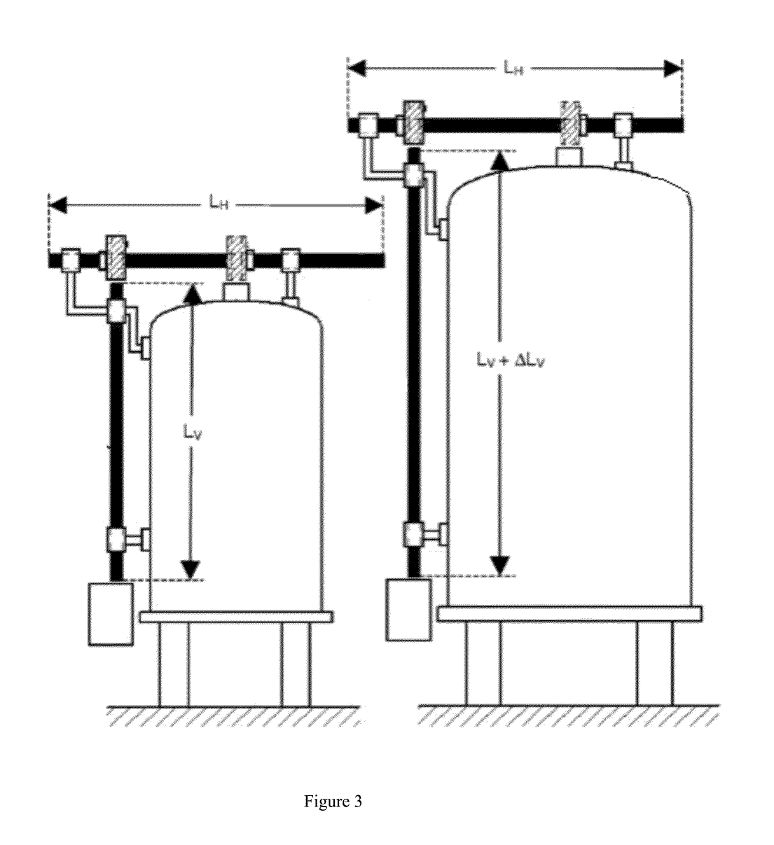

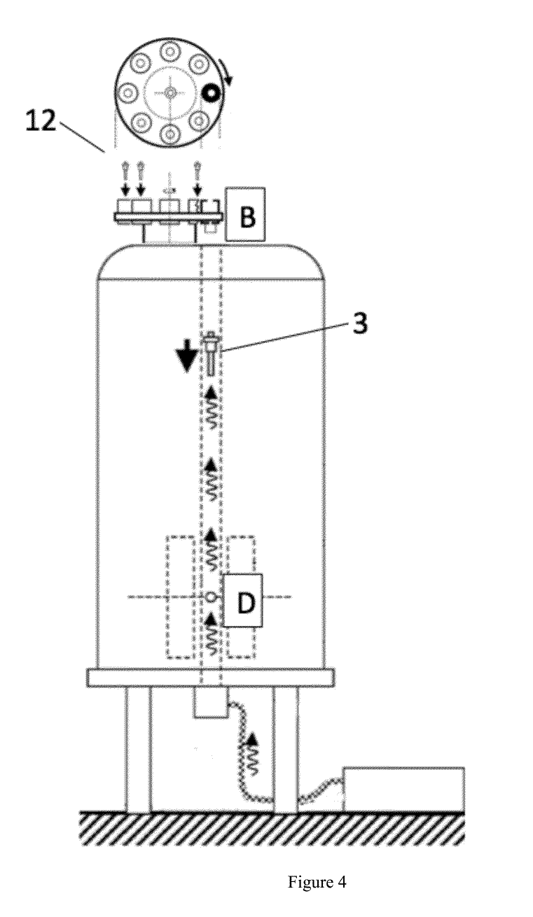

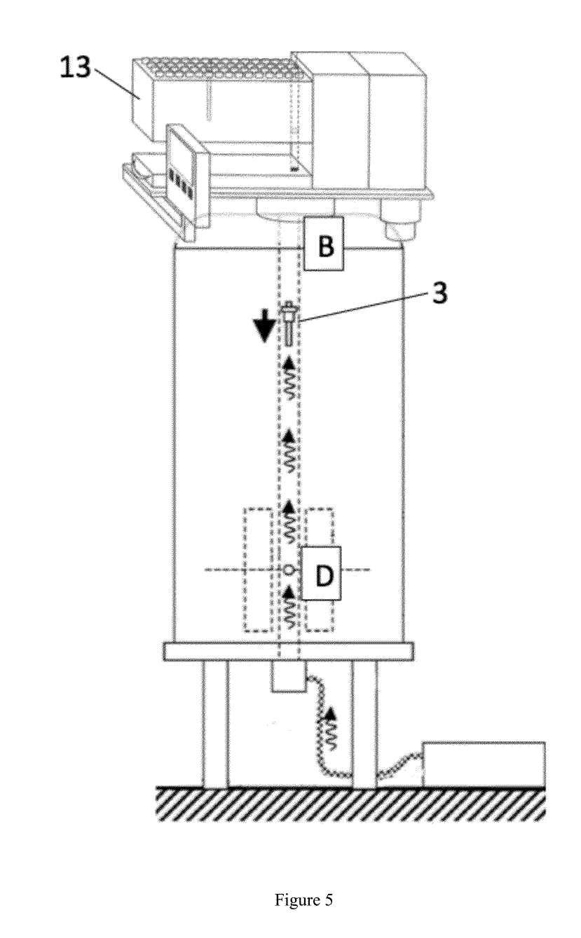

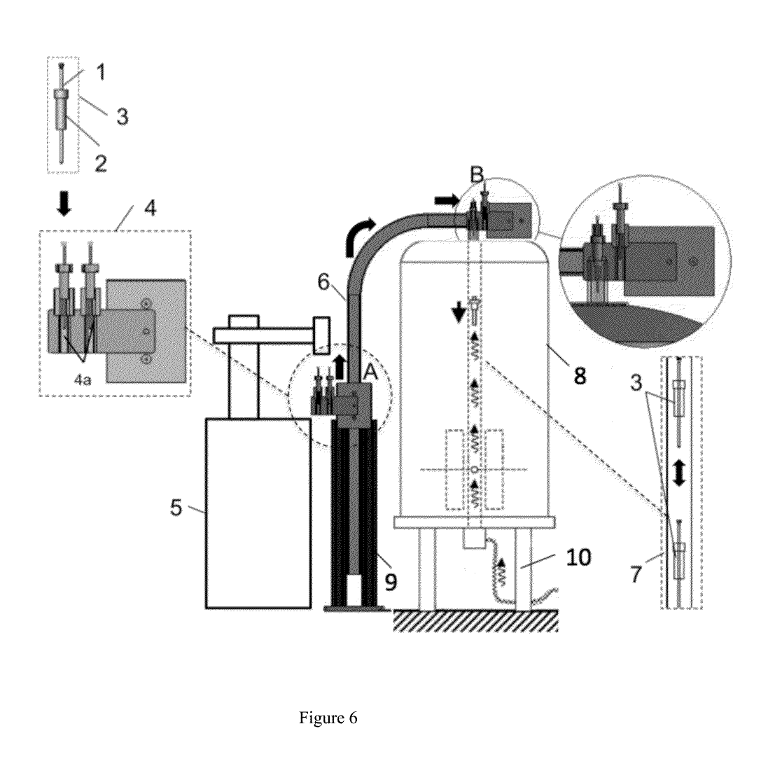

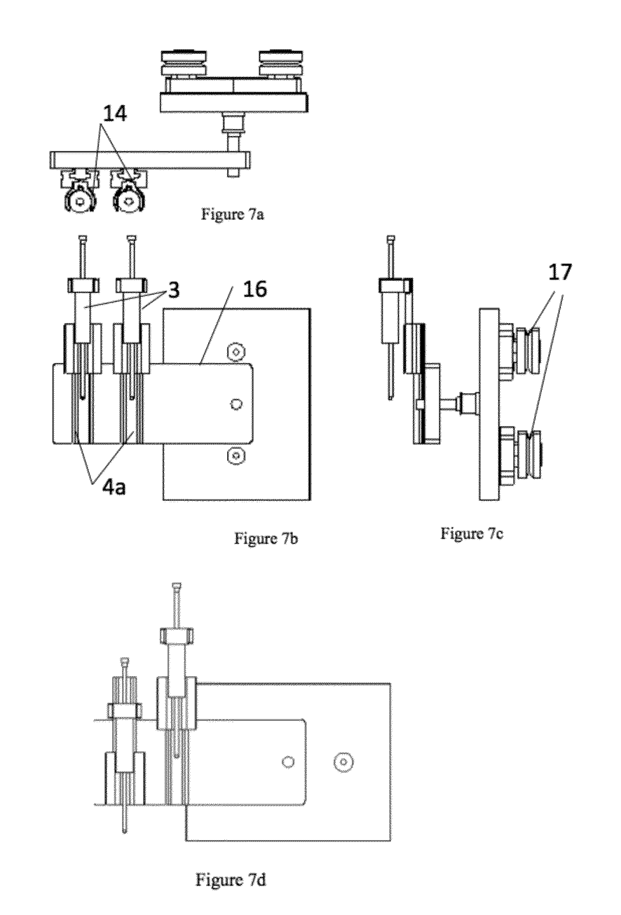

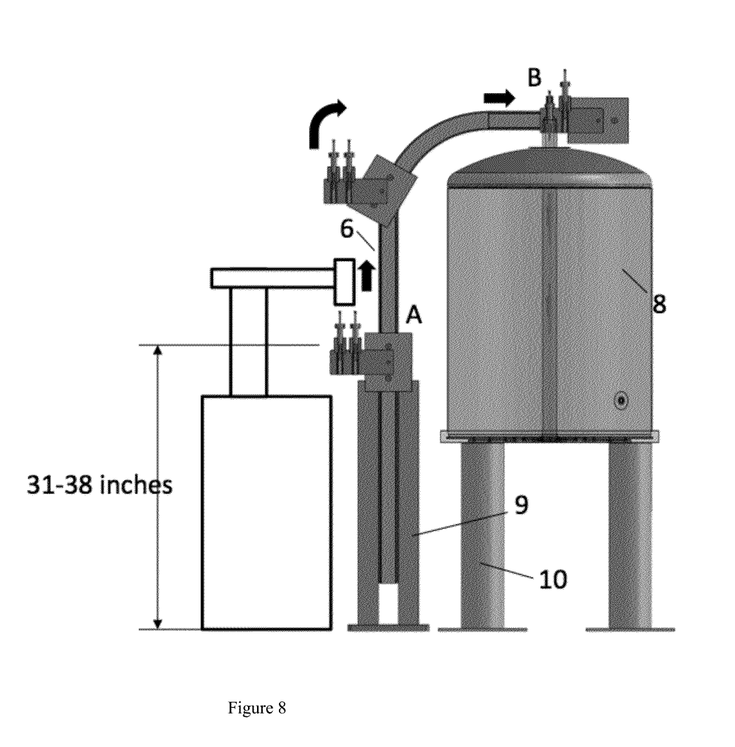

### LIST OF REFERENCE NUMERALS

A. Input point
B. Supply point to the RT tube of the cryostat
C. Intermediary Location
D. Magnetic Center of the superconducting magnet.
LTM Linear Actuator for Transport mechanism 2 for Sample Mail and Sample Case
1. NMR Test tube for holding the liquid or solid sample
2. Sample Container (Turbine)
3. NMR Measuring sample
4. Transport Carrier
4a. Slides with gripper for moving the NMR measuring sample up/down.
5. Standalone Robot (A Standard Cartesian or Pick and Place robot) bolted to the floor.
6. Curvilinear rail
7. Room Temperature (RT) tube of the Cryostat.
8. Super conducting magnet
9. Telescoping legs
10. Vibration Isolated Magnet legs
11. Transport Tube for Bruker Sample Mail [1] and Sample Case[2]
12. Carousel transport device (Sample Changer ASC [4] from JEOL & 7510 AS [3] from Agilent Technologies)
13. Bruker Sample Express [5]
14. Slides that move up and down
16 Rotary link
17 Wheels on which the transport Carrier moves along the Curvilinear rail

### REFERENCE LIST

1. “Sample Mail”, Bruker, http://www.bruker.com/products/menmeautomation/automation/samplemail/overview.html
2. “Sample Case”, Bruker, http://www.bruker.com/products/menmeautomation/automation/samplecase/overview.html, 2009
3. “7510-AS” Auto Sampler, Agilent Technologies (formerly Varian Inc.) http://www.chem.agilent.com/en-US/products-services/Instruments-Systems/Nuclear-Magnetic-Resonance/7510-AS-Autosampler/Pages/default.aspx, 2007
4. “Sample Changer ASC 8/16/24/64”, JEOL USA, http://www.jeolusa.com/PRODUCTS/AnalyticalInstruments/NuclearMagneticResonance/SampleChangers/tabid/389/Default.aspx, 2008
5. “Sample Express”, Bruker, http://www.bruker.com/products/mr/nmeautomation/automation/samplexpress/overview.html
6. “7620-AS” Auto Sampler, Agilent Technologies (formerly Varian Inc.) http://www.chem.agilent.com/en-US/products-services/Instruments-Systems/Nuclear-Magnetic-Resonance/7620-AS-Autosampler/Pages/default.aspx
7. “Sample Jet”, Bruker, http://www.bruker.com/products/menmr/automation/automation/samplejet/overview.html

I claim:

1. A transport device for conveying an NMR measuring sample between an input point, where the sample is inserted into and removed from the transport device, and a supply point where the sample is supplied to a Room Temperature (RT) tube of a cryostat, the input point being both horizontally and vertically spaced apart from the supply point, the device comprising: a Transport Carrier disposed at the input point for receiving the sample; a curvilinear rail along which the Transport Carrier is guided; telescoping leg assemblies which can be used so that a single curvilinear rail be used for all magnet heights; A rotary link attached to the carriage; gyro sensor to ensure that the link is always parallel to the floor and in that the samples are always held vertically up; and two slides attached to the rotary link for inserting or receiving the samples;

2. The transport device of claim 1, wherein the transport device is not attached to the magnet and operates standalone next to the magnet such that no vibrations from the transport device are transmitted to the NMR magnet.

3. The transport device of claim 1, wherein a single curvilinear rail with a guide profile is provided for transporting the sample from the input point to the supply point and vice versa.

4. The transport device of claim 1, where in the legs as well as the curvilinear rail have a plurality of holes such that the same curvilinear rail and legs be used for all magnet heights.

5. The transport device of claim 1, where in the legs for the rail are either bolted to the floor or can be rigidly attached to the Magnet's vibration isolated legs at a prescribed radius away from the magnet center.

6. The transport device of claim 1, which has a Transport Carrier for transporting samples from the input point to supply point and back. Where in the Transport Carrier has a rotary link with two or more slides to receive samples and submit them to the RT tube of the cryostat at the supply point.

7. The transport device of claim 1, where in the slides on the rotary link each have a gripper to grab the outer diameter of the sample holder (turbine) and the slides can traverse up or down to drop off or pick up the sample at the supply point, where the slides are operated with a pneumatic or an piezo-electric motor.

8. The transport device of claim 1, where in the rotary link on the Transport Carrier has a mechanism or operated with a pneumatic or piezo-electric motor to keep the rotary link always parallel to the floor irrespective of its position on the curvilinear rail.

9. The transport device of claim 1, where in the Transport Carrier is operated with a belt drive using a motor or a pneumatic actuator and the motor is positioned away from the magnetic field.

10. The transport device of claim 1, where in a brake is provided to stop the motor in case there is loss of power to prevent the sample from falling down.

11. The transport device of claim 1, where in the Transport Carrier at the input point is at 31-38 inches height from the floor to enable access to the input point from a user seated in a chair or even for a disabled person on a wheel chair be able to access the sample.

12. The transport device of claim 1, where in a standalone robot that is not attached to the transport device of claim 1, is able to submit or pick up samples on to the Transport Carrier at the input point.

13. The standalone robot of claim 11, be a standard pick and place Cartesian robot or a SCARA robot that can be trained to manipulate both plain NMR samples as well as test tubes from magazines and insert them into the sample holders on the Transport Carrier.

14. The standalone robot of claim 11 is also be able to submit or pick up samples which are heated or cooled for the NMR experiment.

15. The transport device of claim 1, where in a thermoelectric device is mounted at the supply point to where the Transport Carrier slides can be arranged to submit the samples or pick up the samples from the thermoelectric device.
